(19) United States
(12) Patent Application Publication
(10) Pub. No.: US 2013/0105761 A1
(43) Pub. Date: May 2, 2013

(54) LIGHT EMITTING DEVICE AND METHOD FOR MANUFACTURING THE SAME

(71) Applicants: Woosik LIM, Seoul (KR); Myeongsoo Kim, Seoul (KR)

(72) Inventors: Woosik LIM, Seoul (KR); Myeongsoo Kim, Seoul (KR)

(21) Appl. No.: 13/412,779

(22) Filed: Mar. 6, 2012

(30) Foreign Application Priority Data
Oct. 31, 2011 (KR) 10-2011-0111981

(51) Int. Cl. H01L 33/04

(52) U.S. Cl. 257/13; 438/47; 257/E33.008

(57) ABSTRACT

A light emitting device and a method for manufacturing the same are disclosed. The light emitting device includes a light emitting structure including a first semiconductor layer, a second semiconductor layer, and an active layer disposed between the first and second semiconductor layers, the light emitting structure being made of a nitride semiconductor having a hexagonal crystal structure, and an irregularity portion formed at a side surface of the light emitting structure, wherein the irregularity portion has a triangular shape at an upper surface thereof, and at least one face of the triangular shape includes a non-polar face of the hexagonal crystal structure.

### CROSS-REFERENCE TO RELATED APPLICATION

This application claims the priority benefit of Korean Patent Application No. 10-2011-0111981, filed on Oct. 31, 2011 in the Korean Intellectual Property Office, the disclosure of which is incorporated herein by reference.

### BACKGROUND

1. Field

Embodiments relate to a light emitting device and a method for manufacturing the same.

2. Description of the Related Art

Fluorescent lamps must be frequently replaced due to occurrence of a dark spot, a short lifespan, etc. Furthermore, they are inconsistent with demand for more eco-friendly illumination systems due to use of fluorescent materials. For this reason, fluorescent lamps are gradually being replaced by other light sources.

Among light emitting devices, there is great interest in light emitting diodes (LEDs) as an alternative light source. LEDs have advantages of semiconductors such as rapid processing speed and low power consumption, are eco-friendly, and have high energy saving effects. Thus, LEDs are a leading next-generation light source. In this regard, practical application of LEDs to replace existing fluorescent lamps is actively underway.

Currently, semiconductor light emitting devices such as LEDs are applied to televisions, monitors, notebooks, cellular phones, and various appliances equipped with display devices. In particular, they are widely used as backlight units to replace existing cold cathode fluorescent lamps (CCFLs).

Group III-V nitride semiconductors are a focus of attention as critical materials of light emitting devices such as LEDs or laser diodes (LDs) due to physical or chemical characteristics thereof. Nitride light emitting devices are commonly grown on a sapphire substrate. Alternatively, nitride light emitting devices are generally grown on a sapphire (Al₂O₃) substrate, are removed using a laser lift-off (LLO) process, and are then formed on a separate conductive substrate.

However, when nitride semiconductors are grown on a sapphire substrate and are isolated, there is a problem in that it is difficult to form irregularity structures at side surfaces of the nitride semiconductors.

### SUMMARY

Embodiments provide a light emitting device capable of achieving improvement in crystal defects and a method for manufacturing the same.

In one embodiment, a light emitting device includes a light emitting structure including a first semiconductor layer, a second semiconductor layer, and an active layer disposed between the first and second semiconductor layers, the light emitting structure being made of a nitride semiconductor having a hexagonal crystal structure, and an irregularity portion formed at a side surface of the light emitting structure, wherein the irregularity portion has a pyramid shape with at least two faces, and at least one face of the pyramid shape includes a non-polar face of the hexagonal crystal structure.

### BRIEF DESCRIPTION OF THE DRAWINGS

Details of embodiments will be more clearly understood from the following detailed description taken in conjunction with the accompanying drawings, in which:

FIG. 1 is a top view illustrating a light emitting device according to an embodiment;

FIG. 2 is a sectional view taken along line A-A′ of the light emitting device shown in FIG. 1;

FIG. 3 is an enlarged view illustrating region “a” of FIG. 1;

FIGS. 4 to 7 are views for explanation of a hexagonal crystal structure of each of a substrate and a nitride semiconductor layer, wherein each face of the hexagonal crystal structure is illustrated;

FIG. 8 is a sectional view illustrating a light emitting device according to another embodiment;

FIG. 9 is a sectional view illustrating a light emitting device according to yet another embodiment;

FIGS. 10 to 15 are views illustrating a method for manufacturing the light emitting device according to the illustrated embodiment;

FIG. 16 is a perspective view illustrating a light emitting device package including a light emitting device according to an exemplary embodiment;

FIG. 17 is a sectional view illustrating the light emitting device package including the light emitting device according to the illustrated exemplary embodiment;

FIG. 18 is a perspective view illustrating a lighting apparatus including a light emitting device according to an exemplary embodiment;

FIG. 19 is a sectional view taken along line C-C′ of the lighting apparatus shown in FIG. 18;

FIG. 20 is an exploded perspective view illustrating a liquid crystal display apparatus including a light emitting device according to an exemplary embodiment; and

FIG. 21 is an exploded perspective view illustrating a liquid crystal display apparatus including a light emitting device according to an exemplary embodiment.

### DETAILED DESCRIPTION OF EMBODIMENTS

Reference will now be made in detail to embodiments, examples of which are illustrated in the accompanying drawings. However, the present disclosure may be embodied in many different forms and should not be construed as limited to the embodiments set forth herein. Rather, these embodiments are provided so that this disclosure will be thorough and complete, and will fully convey the scope of the disclosure to those skilled in the art. The present disclosure is defined only by the categories of the claims. Wherever possible, the same reference numbers will be used throughout the drawings to refer to the same or like parts.

Spatially-relative terms such as “below”, “beneath”, “lower”, “above”, or “upper” may be used herein to describe one element's relationship to another element as illustrated in the Figures. It will be understood that spatially-relative terms are intended to encompass different orientations of the device in addition to the orientation depicted in the Figures. For example, if the device in one of the figures is turned over, elements described as “below” or “beneath” other elements would then be oriented “above” the other elements. The exemplary terms “below” or “beneath” can, therefore, encompass both an orientation of above and below. Since the device may be oriented in another direction, the spatially-relative terms may be interpreted in accordance with the orientation of the device.

The terminology used in the present disclosure is for the purpose of describing particular embodiments only and is not intended to limit the disclosure. As used in the disclosure and the appended claims, the singular forms “a”, “an” and “the” are intended to include the plural forms as well, unless context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, the thickness or size of each layer is exaggerated, omitted, or schematically illustrated for convenience of description and clarity. Also, the size or area of each constituent element does not entirely reflect the actual size thereof.

Angles or directions used to describe the structures of light emitting devices according to embodiments are based on those shown in the drawings. Unless there is, in the specification, no definition of a reference point to describe angular positional relations in the structures of the light emitting devices, the associated drawings may be referred to.

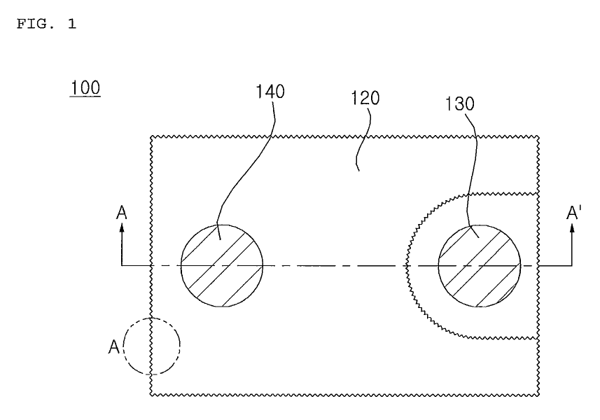

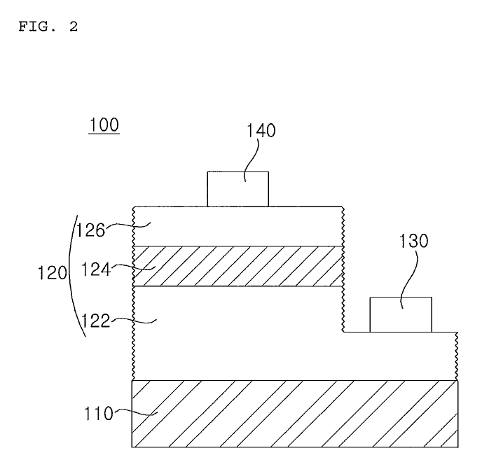

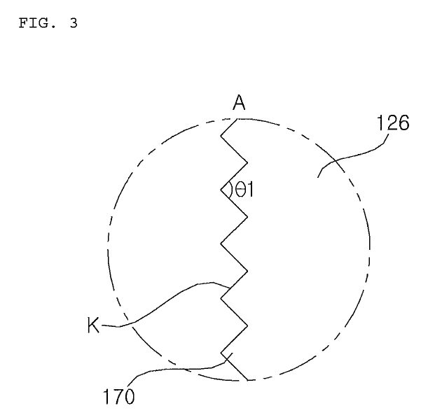

FIG. 1 is a top view illustrating a light emitting device according to an embodiment. FIG. 2 is a sectional view taken along line A-A′ of the light emitting device shown in FIG. 1. FIG. 3 is an enlarged view illustrating region “a” of FIG. 1.

Referring to FIGS. 1 and 2, the light emitting device, which is designated by reference numeral 100, according to the illustrated embodiment may largely include a substrate 110 and a light emitting structure 120. The light emitting structure 120 may contain a nitride semiconductor having a hexagonal crystal structure. For example, the light emitting structure 120 may include a first semiconductor layer 122, a second semiconductor layer 126, and an active layer 124 between the first and second semiconductor layers 122 and 126.

The substrate 110 may be made of any one material having light transmitting properties, for example, sapphire (Al₂O₃), SiC, GaAs, GaN, or ZnO, which has a hexagonal crystal structure, but the present disclosure is not limited thereto. Also, the substrate 110 may be a substrate made of silicon carbide (SiC) having higher thermal conductivity than the sapphire (Al₂O₃) substrate. However, the substrate 110 preferably has a lower refractive index than the first semiconductor layer 122 in order to enhance light extraction efficiency.

Meanwhile, the substrate 110 may be formed with an irregularity pattern (not shown) to enhance light extraction efficiency.

The irregularity pattern may be formed at a surface beneath the surface at which the light emitting structure is formed, and be formed using an etching method. For example, a dry etching method or a wet etching method may be used, but the present disclosure is not limited thereto. In accordance with the irregularity pattern, it may be possible to prevent total reflection of light, and thus to achieve an enhancement in light extraction efficiency.

Also, a buffer layer (not shown) may be disposed on the substrate 110, to reduce lattice misalignment between the substrate 110 and the first semiconductor layer 122 while enabling easy growth of the semiconductor layer. The buffer layer (not shown) may be formed in a low temperature mode, and be made of a material capable of reducing a difference in lattice constants between the semiconductor layer and the substrate. For example, the buffer layer may be made of a material selected from GaN, InN, AlN, AlInN, InGaN, AlGaN, and InAlGaN, but the present disclosure is not limited thereto.

The light emitting structure 120, which includes the first semiconductor layer 122, the active layer 124, and the second semiconductor layer 126, may be formed on the buffer layer (not shown).

The first semiconductor layer 122 may be disposed on the buffer layer (not shown). The first semiconductor layer 122 may be implemented as an n-type semiconductor layer, and may supply electrons to the active layer 124. The first semiconductor layer 122 may be made of, for example, a semiconductor material having a formula of InₓAl_{y}Ga_{1-x-y}N (0≦x≦1, 0≦y≦1, and 0≦x+y≦1). For example, the first semiconductor layer 122 may be made of a semiconductor material selected from GaN, AlN, AlGaN, InGaN, InN, InAlGaN, AlInN, and the like, and may be doped with an n-type dopant such as Si, Ge, Sn, or the like.

The first semiconductor layer 122 may further include an undoped semiconductor layer (not shown) disposed beneath the first semiconductor layer 122, but the present disclosure is not limited thereto. The undoped semiconductor layer refers to a layer formed to enhance crystallinity of the first semiconductor layer 122, and is not doped with the n-type dopant. Accordingly, the undoped semiconductor layer may be equal to the first semiconductor layer 122, except for having lower electrical conductivity than the first semiconductor layer 122.

The active layer 124 may be formed on the first semiconductor layer 122. The active layer 124 may be formed to have a single quantum well structure, a multi quantum well (MQW) structure, a quantum wire structure, a quantum dot structure, or the like, using a Group III-V compound semiconductor material.

When the active layer 124 has the quantum well structure, the active layer 124, for example, may have the single or multi quantum well structure, which includes a well layer having a formula of InₓAl_{y}Ga_{1-x-y}N (0≦x≦1, 0≦y≦1, and 0≦x+y≦1) and a barrier layer having a formula of InₐAl_{b}Ga_{1-a-b}N (0≦a≦1, 0≦b≦1, and 0≦a+b≦1). The well layer may be made of a material having a smaller band gap than the barrier layer. The well layer and the barrier layer may be alternately laminated.

A conductive clad layer (not shown) may be formed over and/or beneath the active layer 124. The conductive clad layer (not shown) may be made of an AlGaN-based semiconductor and have a greater band gap than the active layer 124.

The second semiconductor layer 126 may be implemented as a p-type semiconductor layer so as to inject holes into the active layer 124. The second semiconductor layer 126 may be made of, for example, a semiconductor material having a formula of InₓAl_{y}Ga_{1-x-y}N (0≦x≦1, 0≦y≦1, and 0≦x+y≦1). For example, the second semiconductor layer 126 may be made of a semiconductor material selected from GaN, AlN, AlGaN, InGaN, InN, InAlGaN, AlInN, and the like, and may be doped with a p-type dopant such as Mg, Zn, Ca, Sr, Ba, or the like.

Meanwhile, an intermediate layer (not shown) may be formed between the active layer 124 and the second semiconductor layer 126. The intermediate layer may be an electron blocking layer to prevent electrons injected from the first semiconductor layer 122 to the active layer 124 during application of high current from flowing to the second semiconductor layer 126, without recombination of the electrons in the active layer 124. The intermediate layer has a relatively greater band gap than the active layer 124, thereby preventing electrons injected from the first semiconductor layer 122 from being injected into the second semiconductor layer 126, without recombination of the electrons in the active layer 124. Consequently, it may be possible to enhance recombination probability between the electrons and the holes in the active layer 124 and to prevent current leakage.

The above-mentioned intermediate layer may have a greater band gap than the barrier layer included in the active layer 124, and be formed as a semiconductor layer containing aluminum (Al) such as p-type AlGaN. However, the intermediate layer is not limited to the above-mentioned configurations.

The above-mentioned first semiconductor layer 122, active layer 124, and second semiconductor layer 126 may be formed, for example, using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the present disclosure is not limited thereto.

Also, the conductive dopant in each of the first and second semiconductor layers 122 and 126 may have a uniform or non-uniform doping concentration. That is, a plurality of semiconductor layers may be formed to have various doping concentration distributions, but the present disclosure is not limited thereto.

Alternatively, the first semiconductor layer 122 may be implemented as a p-type semiconductor layer, the second semiconductor layer 126 may be implemented as an n-type semiconductor layer, and a third semiconductor layer (not shown), which includes an n-type or p-type semiconductor layer, may also be formed on the second semiconductor layer 126. Thus, the light emitting device 100 may have at least one of an n-p junction structure, a p-n junction structure, an n-p-n junction structure, and a p-n-p junction structure.

An electrode serves to connect the light emitting device 100 to a power source. The electrode may include a first electrode 130 electrically connected to the first semiconductor layer 122 and a second electrode 140 disposed on the second semiconductor layer 126. A light transmitting electrode layer (not shown) may be formed between the second electrode 140 and the second semiconductor layer 126.

The light transmitting electrode layer may be made of at least one of ITO, IZO(In—ZnO), GZO(Ga—ZnO), AZO(Al—ZnO), AGZO(Al—Ga ZnO), IGZO(In—Ga ZnO), IrOₓ, RuOₓ, RuOₓ/ITO, Ni/IrOₓ/Au, and Ni/IrOₓ/Au/ITO. The light transmitting electrode layer may be formed at a portion of or throughout an outer surface of the second semiconductor layer 126, thereby enabling prevention of a current crowding phenomenon.

The first electrode 130 may be formed on the first semiconductor layer 122. There is no limit as to a formation position of the first electrode 130, and a plurality of first electrodes may also be formed taking into consideration a size of the light emitting device 100 or the like. Furthermore, partial regions of the second semiconductor layer 126 and active layer 124 may be removed, a portion of the first semiconductor layer 122 may be exposed, and the first electrode 130 may be formed on the exposed upper surface of the first semiconductor layer 122, as shown in FIG. 2. However, the present disclosure is not limited to the above-mentioned configurations. For example, the substrate 110 may be removed, and the first electrode 130 may also be formed on the exposed surface of the first semiconductor layer 122.

There is no limit as to a method of removing the upper surface of the first semiconductor layer 122, and, for example, a wet etching method, a dry etching method, or the like may be used.

The second electrode 140 may be disposed on the second semiconductor layer 126.

Referring to FIGS. 1 to 3, the light emitting device 100 may include an irregularity portion 170 formed at a side surface of the light emitting structure 120. The light emitting structure 120 may have a square shape at an outer periphery of an upper surface thereof, and four faces of the square shape may be semi-polar faces of the hexagonal crystal structure. Here, the four faces of the square shape refer to faces at which the irregularity portion 170 is formed.

Particularly referring to FIG. 3, the irregularity portion 170 may have a pyramid shape with at least two faces, and at least one face k of the pyramid shape may include a non-polar face of the hexagonal crystal structure. Furthermore, the pyramid shape may have a triangular shape in section.

The above-mentioned non-polar face may be an M-face {1-100}.

There is no limit as to a size of the irregularity portion 170, and the irregularity portion 170 may have various sizes depending on a size of the light emitting device 100. Also, the irregularity portion 170 may be formed using a wet etching method.

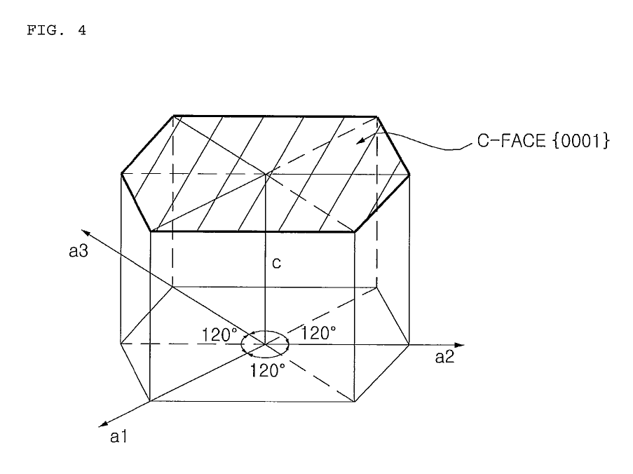

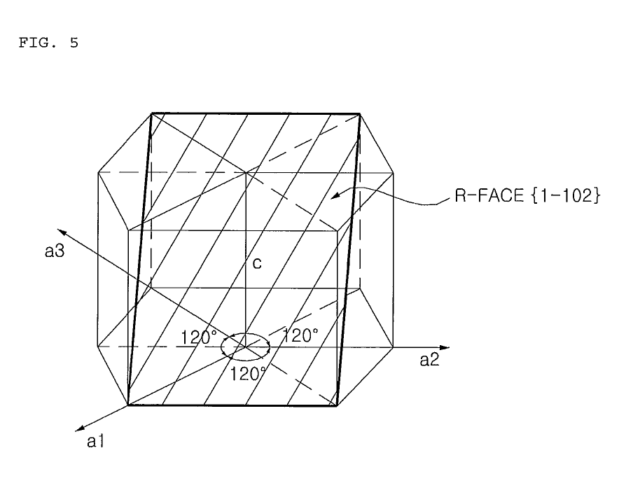

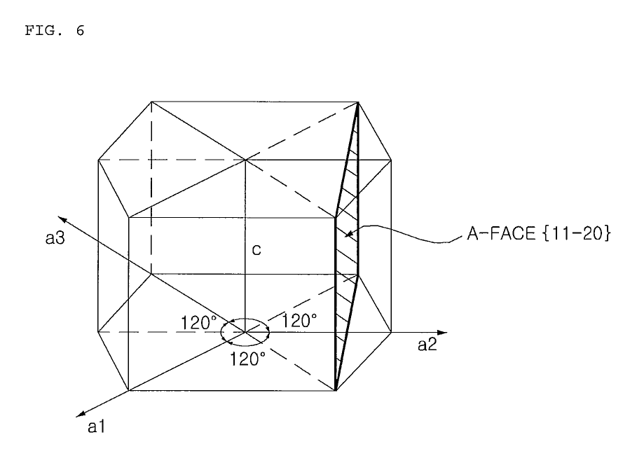

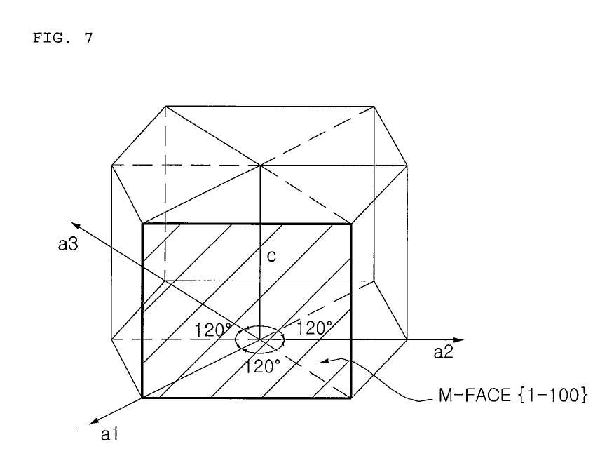

The triangular shape of the irregularity portion 170 may have a vertical angle θ1 which is an obtuse angle, and the pyramid shape of the irregularity portion 170 may include the vertical angle θ1 of 120 degrees. However, the present disclosure is not limited to the above-mentioned configurations. FIGS. 4 to 7 are views for explanation of the hexagonal crystal structure of each of the substrate 110 and a nitride semiconductor layer, wherein each face of the hexagonal crystal structure is illustrated.

Hereinafter, the hexagonal crystal structure of the nitride semiconductor layer will be described with reference to FIGS. 4 to 7. FIGS. 4 to 7 show a C-face {0001}, an A-face {11-20}, an R-face {1-102}, and an M-face {1-100} of the hexagonal crystal structure, respectively.

The nitride semiconductor layer and alloys thereof are the most stable in the hexagonal crystal structure (particularly, a hexagonal wurtzite structure). As shown in FIGS. 4 to 7, such a crystal structure is designated by three basic axes [a₁, a₂, and a₃], which have 120 degree rotational symmetry with respect to one another and are perpendicular to a C-axis [0001] of a vertical direction.

A crystal orientation index is designated by [0000], a family index of the crystal orientation index, which is equal to one crystal orientation index, is designated by <0000>, a face orientation index is designated by (0000), and a family index of the face orientation index, which is equal to one face orientation index, is designated by {0000}.

Accordingly, the above-mentioned A-face {11-20} includes crystal faces, namely, a (−1-120) face, a (−12-10) face, a (1-210) face, a (−2110) face, and a (2-1-10) face exhibited when the hexagonal crystal structure is rotated about the C-axis [0001] by 60 degrees, as well as a (11-20) face.

Similarly, the R-face {1-102} includes crystal faces, namely, a (−1102) face, a (10-12) face, a (−1012) face, a (01-12) face, and a (0-112) face exhibited when the hexagonal crystal structure is rotated about the C-axis [0001] by 60 degrees, as well as a (1-102) face.

Similarly, the M-face {1-100} includes crystal faces, namely, a (−1100) face, a (10-10) face, a (−1010) face, a (01-10) face, and a (0-110) face exhibited when the hexagonal crystal structure is rotated about the C-axis [0001] by 60 degrees, as well as a (1-100) face.

The substrate 100 and the nitride semiconductor layer have the hexagonal crystal structure. That is, the substrate 110 may be made a material having the hexagonal crystal structure, for example, sapphire (Al₂O₃), SiC, GaAs, GaN, ZnO, or the like.

In the case of growing the nitride semiconductor layer on the substrate 110 having the illustrated crystal structure, a nitride thin film may be easily grown and be stable at a high temperature during growth of the nitride semiconductor layer in a C-face {0001} direction. Thus, the substrate 100 is mainly utilized as a substrate for nitride growth. However, polarization effect is generated in the nitride semiconductor layer grown in the C-face {0001} direction. Such polarization effect includes spontaneous polarization generated by symmetric elements included in the crystal structure along the C-axis while gallium layers and nitrogen layers are repeatedly laminated, and piezoelectric polarization generated by occurrence of stress due to characteristics having a difference in lattice constants between nitrides and C-axis orientations equal to one another when a junction structure is formed of a type different from one another. Since the nitride has a greater piezoelectric coefficient than almost every semiconductor material, considerably great polarization may be caused in spite of small strain. An electrostatic field caused by the two polarizations allows an energy band of the quantum well structure to be structurally changed, thereby distorting distributions of electrons and holes. This phenomenon is referred to as quantum confined stark effect (QCSE). In the light emitting device generating light by recombination of electrons and holes, this QCSE may cause low inner quantum efficiency and aggravate electrical and optical characteristics of the light emitting device such as a red shift of a luminous spectrum. In addition, the rapid growth speed of the C-face {0001} tends to increase crystal defects of the nitride semiconductor layer.

The A-face {11-20}, R-face {1-102}, and M-face {1-100} in the hexagonal crystal structure refer to faces having non-polarity or semi-polarity. Although growth of the nitride semiconductor layer is difficult in the A-face {11-20}, R-face {1-102}, and M-face {1-100} compared with the C-face {0001}, the A-face {11-20}, R-face {1-102}, and M-face {1-100} do not generate an electrostatic field by polarization effect occurring in the C-face {0001}, or reduce generation of the electrostatic field.

Meanwhile, in a gallium nitride (GaN) crystal structure, the non-polar face is the M-face {1-100} parallel to the C-axis [0001], whereas the semi-polar face is the A-face {11-20} and the R-face {1-102} inclined about the C-axis [0001].

As described above, when the nitride semiconductor layer is grown in the C-face {0001} direction, the upper surface of the light emitting structure 120 becomes the C-face {0001}, whereas the side surface of the light emitting structure 120 becomes the M-face {1-100}. Here, since the M-face {1-100} is the non-polar face, it is difficult to form an irregularity structure at the M-face {1-100} even when the M-face {1-100} is etched using an etching solution. Furthermore, when the side surface of the light emitting structure 120 has a flat shape, light emitted from the active layer 124 is totally reflected, thereby deteriorating light extraction efficiency of the light emitting device 100.

Therefore, when an isolation process is carried out so that the side surface of the light emitting structure 120 has the semi-polar face of the hexagonal crystal structure, and the side surface of the light emitting structure 120 is etched using the etching solution or the like, the irregularity portion 170 may be easily formed. In this case, the irregularity portion 170 may have a pyramid shape or a triangular shape, and one face of the pyramid shape may be the M-face {1-100} which is the non-polar face. When the irregularity portion 170 is formed at the side surface of the light emitting structure 120, total reflection of light emitted from the active 124 may be reduced, thereby achieving an enhancement in luminous efficiency of the light emitting device 100.

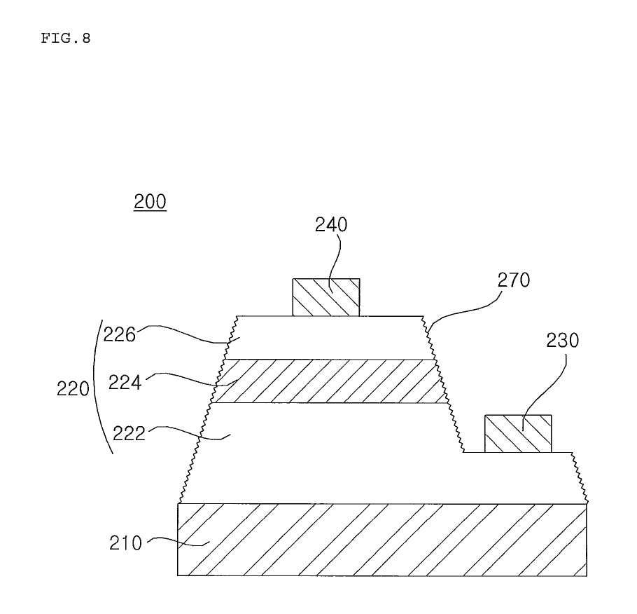

FIG. 8 is a sectional view illustrating a light emitting device according to another embodiment.

Referring to FIG. 8, the light emitting device, which is designated by reference numeral 200, according to the illustrated embodiment differs from the embodiment illustrated in FIG. 2 in that a side surface of a light emitting structure 220 includes an inclined surface.

The inclined surface may be intentionally or naturally formed in an isolation process, but the present disclosure is not limited thereto.

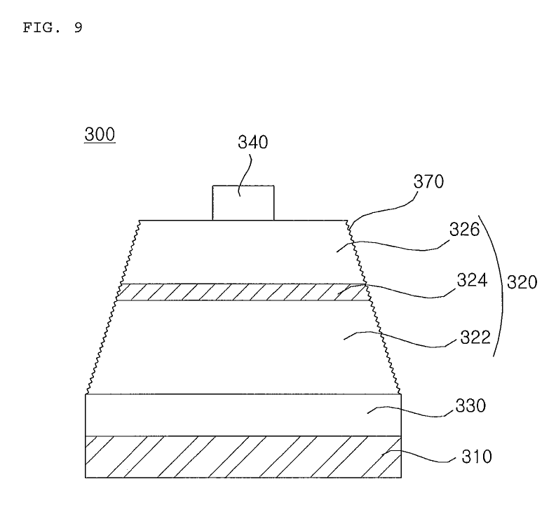

FIG. 9 is a sectional view illustrating a light emitting device according to yet another embodiment.

Referring to FIG. 9, the light emitting device, which is designated by reference numeral 300, according to the illustrated embodiment is a vertical type light emitting device. The light emitting device 300 in the illustrated embodiment may include a support member 310, a first electrode layer 330 disposed on the support member 310, a light emitting structure 320 including a first semiconductor layer 322, an active layer 324, and a second semiconductor layer 326, and a second electrode 340.

The support member 310 may be made of a material having superior thermal conductivity, or alternatively made of a conductive material. For example, the support member 310 may be formed using a metal material or conductive ceramics. The support member 310 may have a single layer structure. Alternatively, the support member 310 may have a double layer structure or a multilayer structure having three or more layers.

That is, the support member 310 may be made of a metal, for example, any one selected from gold (Au), nickel (Ni), tungsten (W), molybdenum (Mo), copper (Cu), aluminum (Al), tantalum (Ta), silver (Ag), platinum (Pt), and chromium (Cr), or made of an alloy containing two or more materials. Also, the support member 310 may be formed by laminating two or more layers of different materials. Furthermore, the support member 310 may be implemented as a carrier wafer made of a material such as Si, Ge, GaAs, ZnO, SiC, SiGe, GaN, or Ga₂O₃. Such a support member 310 functions to easily dissipate heat generated from the light emitting device 300, and thus to achieve an enhancement in thermal stability of the light emitting device 300.

Meanwhile, the first electrode layer 330 may be formed on the support member 310. The first electrode layer 330 may include at least one of an ohmic layer (not shown), a reflective layer (not shown), and a bonding layer (not shown). Although the first electrode layer 330, for example, may have a structure of ohmic layer/reflective layer/bonding layer, a structure of ohmic layer/reflective layer, or a structure of reflective layer (including ohmic characteristics)/bonding layer, the present disclosure is not limited thereto. For example, the first electrode layer 330 may have a structure in which the reflective layer and the ohmic layer are sequentially laminated over the bonding layer.

The reflective layer (not shown) may be disposed between the ohmic layer (not shown) and the bonding layer (not shown). The reflective layer may be made of a material having high reflectance, for example, Ag, Ni, Al, Rh, Pd, Ir, Ru, Mg, Zn, Pt, Au, or Hf, or made of a material consisting of a selective combination thereof. Alternatively, the reflective layer may be formed to have a multilayer structure using the metal materials and a light transmitting conductive material such as IZO, IZTO, IAZO, IGZO, IGTO, AZO, ATO, or the like. The reflective layer (not shown) may have a laminated structure of IZO/Ni, AZO/Ag, IZO/Ag/Ni, AZO/Ag/Ni, or the like. When the reflective layer (not shown) is made of a material coming into ohmic contact with the light emitting structure 320 (for example, the first semiconductor layer 322), the ohmic layer (not shown) need not be separately formed. However, the present disclosure is not limited to the above-mentioned configurations.

The ohmic layer (not shown) may come into ohmic contact with a lower surface of the light emitting structure 320, and be formed to have a layer or a plurality of patterns. For the ohmic layer, a light transmitting electrode layer or a metal may be selectively used. For example, the ohmic layer may be implemented as a single layer structure or a multilayer structure, using at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), gallium zinc oxide (GZO), IrOₓ, RuOₓ, RuOₓ/ITO, Ni, Ag, Ni/IrOₓ/Au, and Ni/IrOₓ/Au/ITO. The ohmic layer (not shown) serves to smoothly inject carriers into the first semiconductor layer 322, but it may not be necessary to form the ohmic layer.

The first electrode layer 330 may include the bonding layer (not shown). In this case, the bonding layer (not shown) may include a barrier metal or a bonding metal. For example, the bonding layer may contain at least one of Ti, Au, Sn, Ni, Cr, Ga, In, Bi, Cu, Ag, and Ta, but the present disclosure is not limited thereto.

The light emitting structure 320 may contain a nitride semiconductor having a hexagonal crystal structure, and include at least the first semiconductor layer 322, the active layer 324, and the second semiconductor layer 326. The active layer 324 may be interposed between the first semiconductor layer 322 and the second semiconductor layer 326.

The first semiconductor layer 322 may be formed on the first electrode layer 330. The first semiconductor layer 322 may be implemented as a p-type semiconductor layer doped with a p-type dopant. The p-type semiconductor layer may be made of a semiconductor material having a formula of InₓAl_{y}Ga_{1-x-y}N (0≦x≦1, 0≦y≦1, and 0≦x+y≦1). For example, the p-type semiconductor layer may be made of a semiconductor material selected from GaN, AlN, AlGaN, InGaN, InN, InAlGaN, AlInN, and the like, and be doped with a p-type dopant such as Mg, Zn, Ca, Sr, Ba, or the like.

The active layer 324 may be formed on the first semiconductor layer 322. The active layer 324 may be formed to have a single quantum well structure, a multi quantum well (MQW) structure, a quantum wire structure, a quantum dot structure, or the like, using a Group III-V compound semiconductor material.

When the active layer 324 has the quantum well structure, the active layer 324, for example, may have the single or multi quantum well structure, which includes a well layer having a formula of InₓAl_{y}Ga_{1-x-y}N (0≦x≦1, 0≦y≦1, and 0≦x+y≦1) and a barrier layer having a formula of InₐAl_{b}Ga_{1-a-b}N (0≦a≦1, 0≦b≦1, and 0≦a+b≦1). The well layer may be made of a material having a smaller band gap than the barrier layer.

Also, when the active layer 430 has the multi quantum well structure, each well layer (not shown) may have a different indium (In) content and band gap.

A conductive clad layer (not shown) may be formed over and/or beneath the active layer 324. The conductive clad layer (not shown) may be made of an AlGaN-based semiconductor and have a greater band gap than the active layer 324.

Meanwhile, an intermediate layer (not shown) may be formed between the active layer 324 and the first semiconductor layer 322. The intermediate layer may be an electron blocking layer to prevent electrons injected from the second semiconductor layer 326 to the active layer 324 during application of high current from flowing to the first semiconductor layer 322, without recombination of the electrons in the active layer 324. The intermediate layer (not shown) has a relatively greater band gap than the active layer 324, thereby preventing electrons injected from the second semiconductor layer 326 from being injected into the first semiconductor layer 322, without recombination of the electrons in the active layer 324. Thus, it may be possible to enhance recombination probability between the electrons and the holes in the active layer 324 and to prevent current leakage.

Here, the intermediate layer may have a greater band gap than the barrier layer included in the active layer 324, and be formed as a semiconductor layer, for example, containing Al such as AlGaN. However, the intermediate layer is not limited to the above-mentioned configurations.

The second semiconductor layer 326 may be formed on the active layer 324. The second semiconductor layer 326 may be implemented as an n-type semiconductor layer. The n-type semiconductor layer, for example, may be made of a semiconductor material having a formula of InₓAl_{y}Ga_{1-x-y}N (0≦x≦1, 0≦y≦1, and 0≦x+y≦1). For example, the n-type semiconductor layer may be made of a semiconductor material selected from GaN, AlN, AlGaN, InGaN, InN, InAlGaN, AlInN, and the like, and be doped with an n-type dopant such as Si, Ge, Sn, Se, Te, or the like.

Meanwhile, the light emitting structure 320 may include a third semiconductor layer (not shown), which is disposed on the second semiconductor layer 326 and has an opposite polarity to the second semiconductor layer 326. Alternatively, the first semiconductor layer 322 may be implemented as an n-type semiconductor layer, and the second semiconductor layer 326 may be implemented as a p-type semiconductor layer. Thus, the light emitting structure 320 may have at least one of an N-P junction structure, a P-N junction structure, an N-P-N junction structure, and a P-N-P junction structure.

The light emitting structure 320 may be formed, at an upper portion thereof, with a light extraction structure (not shown).

The light extraction structure may be formed at a partial region of or throughout an upper surface of the second semiconductor layer 326. The light extraction structure may be formed by carrying out an etching process upon at least a partial region of the upper surface of the second semiconductor layer 326, but the present disclosure is not limited thereto. The etching process may include a wet etching process and/or a dry etching process. According to carrying out the etching process, the upper surface of the second semiconductor layer 326 or light transmitting electrode layer (not shown) may have a roughness to form the light extraction structure. The roughness may be irregularly formed in a random size, but the present disclosure is not limited thereto. The roughness refers to an uneven surface, and may include at least one of a texture pattern, an irregularity pattern, and an uneven pattern.

The roughness may be formed, at a lateral section thereof, to have various shapes such as a circular prism shape, a polygonal prism shape, a conical shape, a polygonal pyramid shape, a truncated conical shape, and a truncated polygonal pyramid shape, and preferably has a pyramid shape.

The light extraction structure may be formed using a photo electro chemical (PEC) method or the like, but the present disclosure is not limited thereto. Since the light extraction structure is formed at the upper surface of the light transmitting electrode layer (not shown) or second semiconductor layer 326, it may be possible to prevent light generated from the active layer 324 from being totally reflected from the upper surface of the light transmitting electrode layer (not shown) or second semiconductor layer 326, thereby preventing re-absorption or scattering of light. As a result, light extraction efficiency of the light emitting device 300 may be enhanced.

The second electrode 340, which is electrically connected to the second semiconductor layer 326, may be formed on the second semiconductor layer 326, and include at least one pad and/or an electrode having a predetermined pattern. The second electrode 340 may be disposed at a center region, an outer region, or a corner region of the upper surface of the second semiconductor layer 326, but the present disclosure is not limited thereto. The second electrode 340 may be disposed at a region different from the upper surface of the second semiconductor layer 326, but the present disclosure is not limited thereto.

The light emitting device 300 may include an irregularity portion 370 formed at a side surface of the light emitting structure 320. The light emitting structure 320 may have a square shape at an outer periphery of an upper surface thereof, and four faces of the square shape may be semi-polar faces of a hexagonal crystal structure. Here, the four faces of the square shape refer to faces at which the irregularity portion 370 is formed.

The irregularity portion 370 may have a triangular shape at an upper surface thereof, and at least one face of the triangular shape may include a non-polar face of the hexagonal crystal structure. The above-mentioned non-polar face may be an M-face {1-100}. The configuration of the irregularity portion 370 is the same as described above.

Accordingly, since the light emitting device 300 in the illustrated embodiment may easily form the irregularity portion at the side surface of the light emitting structure 320, it may be possible to reduce total reflection of light at the side surface of the light emitting structure 320. As a result, luminous efficiency of the light emitting device 300 may be enhanced.

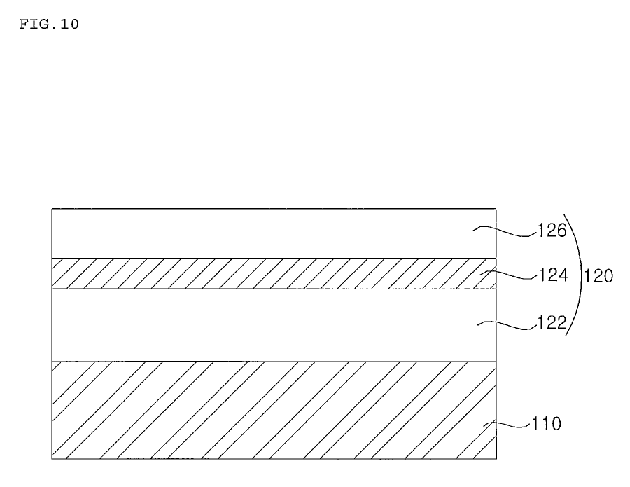

FIGS. 10 to 15 are views illustrating a method for manufacturing the light emitting device according to the illustrated embodiment.

The method for manufacturing the light emitting device according to the illustrated embodiment is as follows.

Referring to FIG. 10, first, the substrate 110 having the hexagonal crystal structure is provided.

Here, the substrate 110 may contain any one of materials having light transmitting properties, for example, sapphire (Al₂O₃), SiC, GaAs, GaN, and ZnO.

Subsequently, the nitride semiconductor layer, which has the hexagonal crystal structure and is biased by 30 degrees with respect to a hexagonal crystal orientation of the substrate 110, may be grown on the substrate 100. The nitride semiconductor layer may include the light emitting structure 120, and the light emitting structure 120, for example, may include the first semiconductor layer 122, the second semiconductor layer 126, and the active layer 124 between the first and second semiconductor layers 122 and 126. Since the first semiconductor layer 122, the active layer 124, and the second semiconductor layer 126 are similar to the configuration illustrated in FIG. 1, no description will be given thereof and the growth method thereof is the same as described above.

Although not shown, the buffer layer (not shown) may be formed between the substrate 110 and the light emitting structure 120.

The buffer layer (not shown) may be made of a combination of Group III and Group V elements, or be made of any one of GaN, InN, AlN, InGaN, AlGaN, InAlGaN, and AlInN. The buffer layer may also be doped with a dopant.

The undoped semiconductor layer (not shown) may be formed over the substrate 110 or the buffer layer (not shown). Any one or both of the buffer layer (not shown) and undoped semiconductor layer (not shown) may be formed or omitted. The present disclosure is not limited thereto.

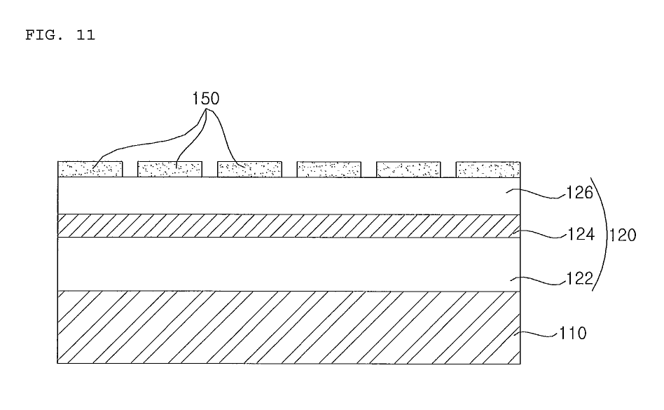

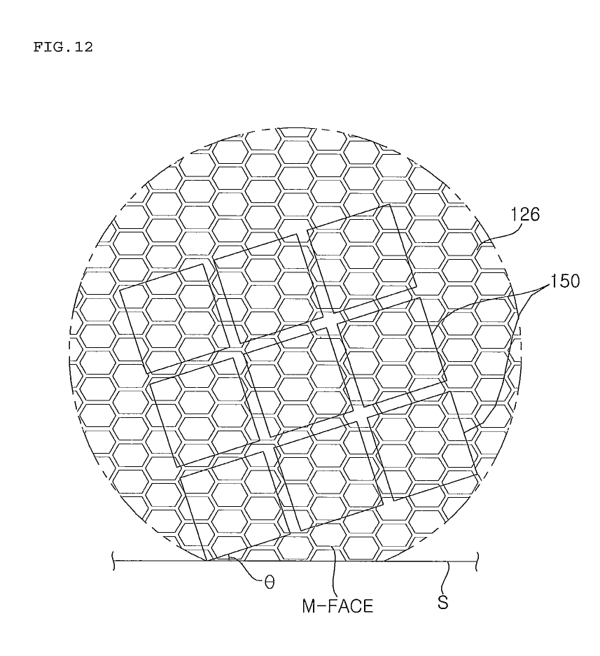

FIG. 11 is a sectional view illustrating a shape in which mask patterns are disposed on the nitride semiconductor layer. FIG. 12 is a top view illustrating the shape in which the mask patterns are disposed on the nitride semiconductor layer as viewed from the top.

Referring to FIGS. 11 and 12, subsequently, a plurality of mask patterns 150 having a square shape is disposed on the nitride semiconductor layer (for example, the light emitting structure 120). Here, each mask pattern 150 may contain an anti-corrosive material, for example, silicon dioxide (SiO₂), but the present disclosure is not limited thereto. In this case, an angle θ between a side surface of the square shaped mask pattern 150 and a datum level s may be formed to have a range of 0 degree to 30 degrees or a range of 30 degrees to 45 degrees. Here, the datum level s may mean a face formed as the A-face of the hexagonal crystal structure of the substrate 110. That is, when the substrate 100 contains gallium nitride (GaN), the datum level s means the A-face of the GaN crystal structure.

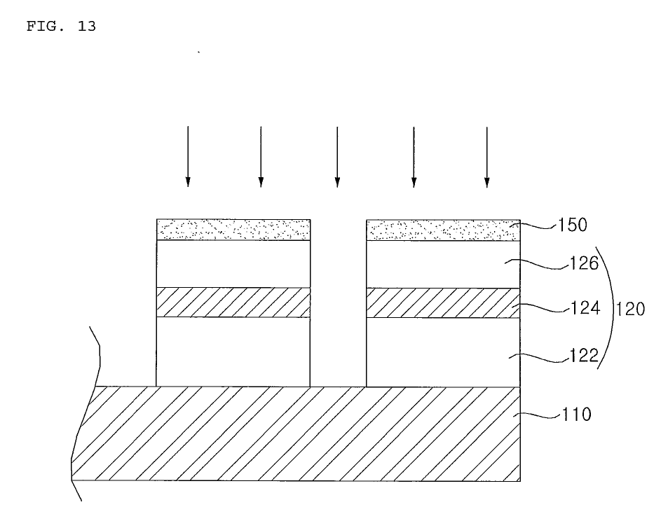

Referring to FIG. 13, subsequently, the nitride semiconductor layer is divided into a plurality of light emitting structures s1 and s2 (isolation). Here, division of the nitride semiconductor layer may be carried out by a wet etching method, but the present disclosure is not limited thereto.

The nitride semiconductor layer is divided into a plurality of light emitting structures s1 and s2 through an isolation process. When the mask patterns 150 are disposed at the above-mentioned angle, the side surface of each light emitting structure s1 or s2 has the semi-polar face, for example, the A-face {11-20}, without having the M-face {1-100} of the hexagonal crystal structure. Since the A-face {11-20}, at which an irregularity structure is easily formed by a wet etching method, forms the side surface of the light emitting structure s1 or s2, the side surface of the light emitting structure s1 or s2 may be easily formed with the irregularity structure in a subsequent process.

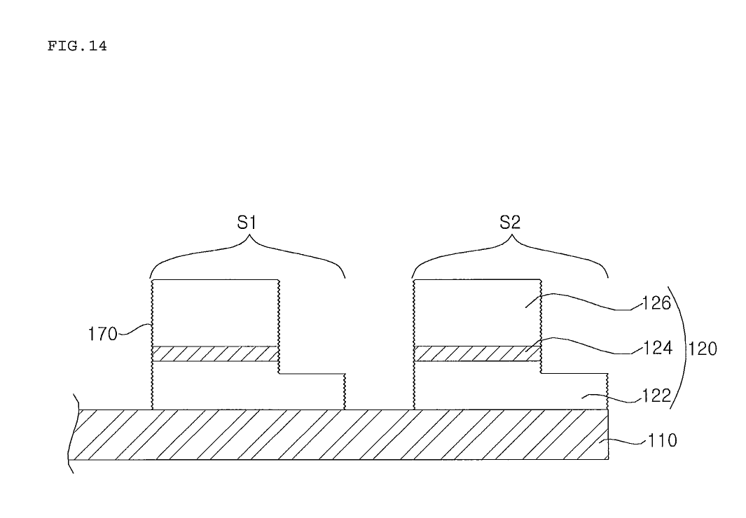

Referring to FIG. 14, subsequently, partial regions of the second semiconductor layer 126 and the active layer 124 of each light emitting structure s1 or s2 are etched so as to expose the first semiconductor layer 122. Here, a wet etching method, a dry etching method, or a laser lift-off (LLO) may be used to etch the layers, but the present disclosure is not limited thereto.

Also, the side surface of the light emitting structure s1 or s2 may be formed with the irregularity portion 170 by wet etching of the nitride semiconductor layer. The irregularity portion 170 may also be formed throughout the side surface of the light emitting structure s1 or s2, or may also be formed at an upper surface of the light emitting structure s1 or s2. Here, formation of the irregularity portion 170 may be carried out using at least one etching solution selected from the group consisting of KOH, HF, NaOH, and H₃PO₄, but the present disclosure is not limited thereto.

The irregularity portion 170 may have a triangular shape at an upper surface thereof, and at least one face of the triangular shape may include a non-polar face of the hexagonal crystal structure.

The above-mentioned non-polar face may be the M-face {1-100}.

There is no limit as to a size of the irregularity portion 170, and the irregularity portion 170 may have various sizes depending on sizes of the light emitting structures s1 and s2.

The triangular shape of the irregularity portion 170 may have the vertical angle which is an obtuse angle, and the triangular shape of the irregularity portion 170 may include the vertical angle of 120 degrees. However, the present disclosure is not limited to the above-mentioned configurations.

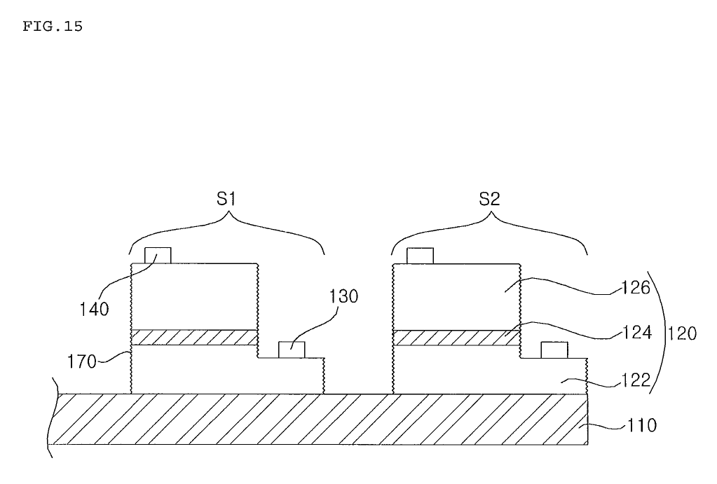

Referring to FIG. 15, subsequently, the first electrode 130 may be formed on the first semiconductor layer 122, and the second electrode 140 may be formed on the second semiconductor layer 126. Alternatively, the first electrode 130 may also be formed beneath the first semiconductor layer 122 after removing the substrate 110, but the present disclosure is not limited thereto.

Thereafter, it may also be possible to carry out a process of cutting the substrate 110 into the same segments as a plurality of light emitting structures s1 and s2.

In accordance with the method for manufacturing the light emitting device in the illustrated embodiment, the irregularity structure is easily formed at the side surface of the light emitting structure s1 or s2, thereby achieving enhancements in operation convenience and luminous efficiency of the light emitting device.

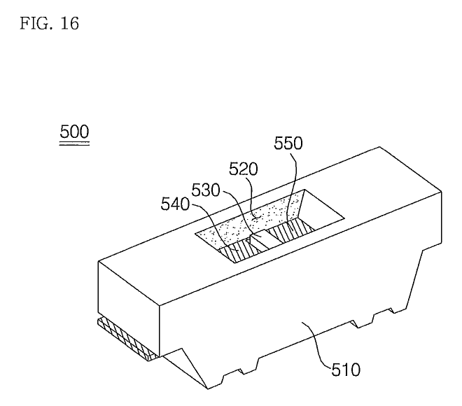

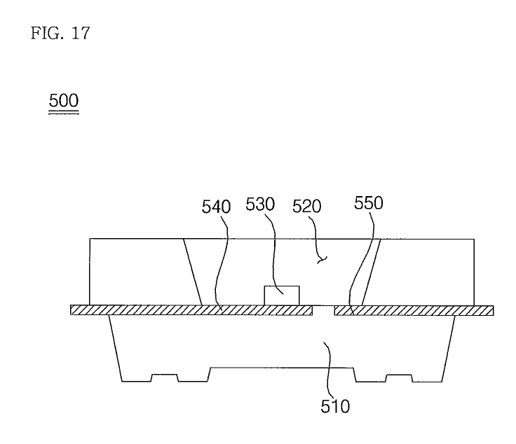

FIG. 16 is a perspective view illustrating a light emitting device package including a light emitting device according to an exemplary embodiment. FIG. 17 is a sectional view illustrating the light emitting device package including the light emitting device according to the illustrated exemplary embodiment.

Referring to FIGS. 16 and 17, the light emitting device package, which is designated by reference numeral 500, may include a body 510 formed with a cavity 520, first and second lead frames 540 and 550 mounted on the body 510, a light emitting device 530 electrically connected to the first and second lead frames 540 and 550, and an encapsulant (not shown) filling the cavity 520 so as to cover the light emitting device 530.

The body 510 may be made of at least one of a resin material such as polyphthalamide (PPA), silicon (Si), aluminum (Al), aluminum nitride (AlN), liquid crystal polymer such as photo sensitive glass (PSG), polyamide 9T (PA9T), syndiotactic polystyrene (SPS), a metal material, sapphire (Al₂O₃), and beryllium oxide (BeO), or may be a Printed Circuit Board (PCB). The body 510 may be formed by an injection molding process, an etching process, or the like, but the present disclosure is not limited thereto.

The body 510 may be formed, at an inner surface thereof, with an inclined surface. In accordance with the inclination of the inclined surface, a reflective angle of light emitted from the light emitting device 530 may be varied. Thus, an orientation angle of outwardly emitted light may be adjusted.

As the orientation angle of light decreases, the convergence of light outwardly emitted from the light emitting device 530 increases. On the other hand, as the orientation angle of light increases, the convergence of light outwardly emitted from the light emitting device 530 decreases.

When viewed from the top, the cavity 520 formed at the body 510 may have a circular shape, a square shape, a polygonal shape, an elliptical shape, or the like. Also, the cavity 520 may have curved corners, but present disclosure is not limited thereto.

The light emitting device 530 is mounted on the first lead frame 540. The light emitting device 530, for example, may be a light emitting device to emit red, green, blue, white light or the like, or a light emitting device to emit ultraviolet (UV) light, but the present disclosure is not limited thereto. In addition, one or more light emitting devices may be mounted.

The above-mentioned embodiment may be applied to a horizontal type light emitting device having a structure in which electrical terminals of the light emitting device 530 are formed at an upper surface thereof, a vertical type light emitting device having a structure in which electrical terminals of the light emitting device 530 are formed at respective upper and lower surfaces thereof, or a flip chip type light emitting device.

The encapsulant (not shown) may fill the cavity 520 so as to cover the light emitting device 530.

The encapsulant (not shown) may be made of silicon, epoxy resin, or other resin material. The encapsulant may be formed by filling the cavity 520 with an encapsulating material, and curing the filled material using ultraviolet light or heat.

The encapsulant (not shown) may contain a fluorescent substance. The kind of the fluorescent substance may be selected depending on a wavelength of light emitted from the light emitting device 530 so that the light emitting device package 500 may realize emission of white light.

The fluorescent substance may be any one of a blue, bluish green, green, yellowish green, yellow, yellowish red, orange, and red luminous fluorescent substances depending on the wavelength of light emitted from the light emitting device 530.

That is, the fluorescent substance may be excited by light emitted from the light emitting device 530 at a first wavelength, so as to generate light of a second wavelength. For example, when the light emitting device 530 is a blue light emitting diode and the fluorescent substance is a yellow fluorescent substance, the yellow fluorescent substance is excited by blue light, thereby emitting yellow light. In this case, the light emitting device package 500 may provide white light as the blue light generated from the blue light emitting diode and the yellow light generated in accordance with the excitation by the blue light are mixed.

Similarly, when the light emitting device 530 is a green light emitting diode, a magenta fluorescent substance or a mixture of blue and red fluorescent substances may be used as the fluorescent substance. Also, when the light emitting device 530 is a red light emitting diode, a cyan fluorescent substance or a mixture of blue and green fluorescent substances may be used as the fluorescent substance.

The fluorescent substance may be a known fluorescent substance such as a YAG-based, TAG-based, sulfide-based, silicate-based, aluminate-based, nitride-based, carbide-based, nitridosilicate-based, borate-based, fluoride-based, or phosphate-based fluorescent substance.

The first and second lead frames 540 and 550 may contain at least one of metal materials, for example, titanium (Ti), copper (Cu), nickel (Ni), gold (Au), chromium (Cr), tantalum (Ta), platinum (Pt), tin (Sn), silver (Ag), phosphor (P), aluminum (Al), indium (In), palladium (Pd), cobalt (Co), silicon (Si), germanium (Ge), hafnium (Hf), ruthenium (Ru), and iron (Fe), or an alloy thereof. The first and second lead frames 540 and 550 may also be formed to have a single layer structure or a multilayer structure, but the present disclosure is not limited thereto.

The first and second lead frames 540 and 550 are spaced apart from each other and are electrically isolated from each other. The light emitting device 530 may be mounted on the first and second lead frames 540 and 550. The first and second lead frames 540 and 550 may be electrically connected to each other by directly coming into contact with the light emitting device 530 or through a conductive material such as a soldering member (not shown). Also, the light emitting device 530 may be electrically connected to the first and second lead frames 540 and 550 using a wire bonding method, but the present disclosure is not limited thereto. Accordingly, when a power source is connected to the first and second lead frames 540 and 550, power may be applied to the light emitting device 530. Meanwhile, a plurality of lead frames (not shown) may be mounted within the body 510, and each of the lead frames (not shown) may be electrically connected to the light emitting device 530. However, the present disclosure is not limited to the above-mentioned configurations.

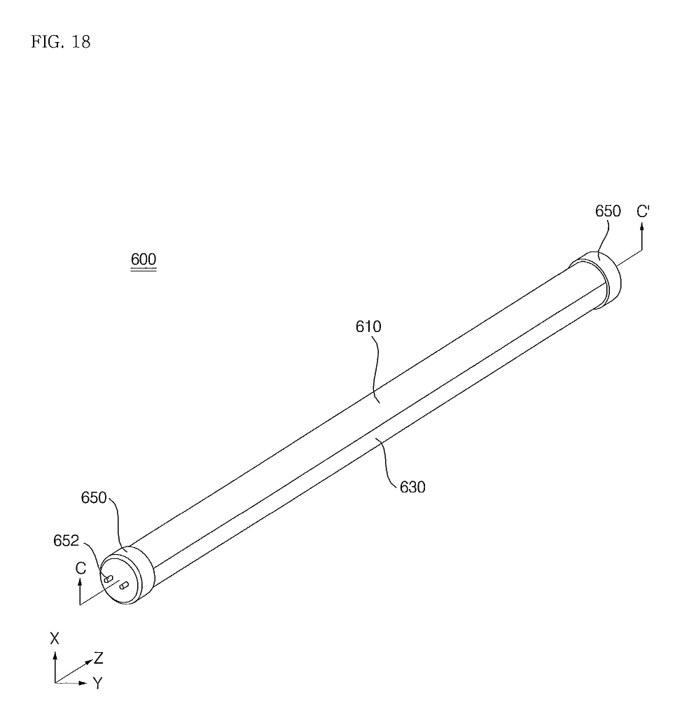

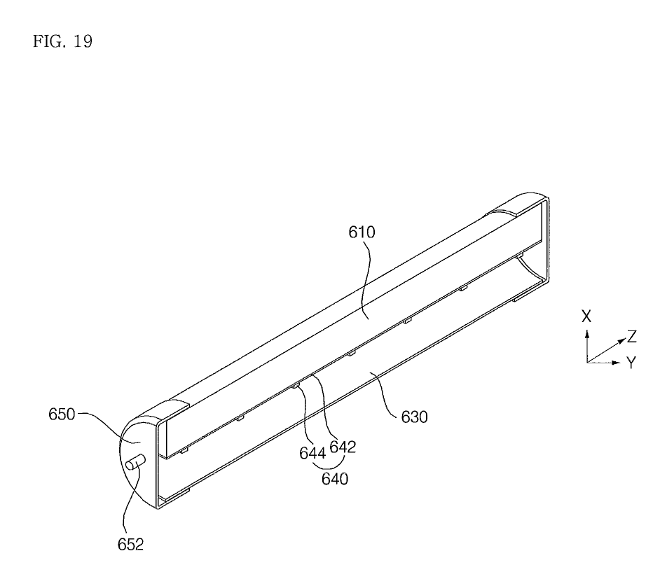

FIG. 18 is a perspective view illustrating a lighting apparatus including a light emitting device according to an exemplary embodiment. FIG. 19 is a sectional view taken along line C-C′ of the lighting apparatus shown in FIG. 18.

Referring to FIGS. 18 and 19, the lighting apparatus 600 may include a body 610, a cover 630 coupled to the body 610, and end caps 650 located at opposite ends of the body 610.

A light emitting device module 640 is coupled to a lower surface of the body 610. The body 610 may be made of a metal material having superior conductivity and superior heat radiation effects so as to outwardly dissipate heat generated from the light emitting device module 640 through an upper surface of the body 610.

Light emitting device packages 644 may be mounted on a PCB 642 in multiple rows while having various colors, to form a multi-color array. The light emitting device packages 644 may be mounted at the same distance, or may be mounted at different distances to enable brightness adjustment, if necessary. The PCB 642 may be a metal core PCB (MCPCB), a flame retardant-4 (FR4) PCB, or the like.

Each light emitting device package 644 may include an extended lead frame (not shown) so that it may have an enhanced heat dissipation function. Thus, it may be possible to enhance the reliability and efficiency of the light emitting device package 644. In addition, it may be possible to extend the lifespan of light emitting device packages 644 and the lighting apparatus 600 including the light emitting device packages 644.

The cover 630 may have a circular shape to enclose the lower surface of the body 610, but the present disclosure is not limited thereto.

The cover 630 serves to protect the light emitting device module 640 from external foreign matter, etc. The cover 630 may contain light diffusion particles to achieve anti-glare effects and uniform emission of light generated from the light emitting device packages 644. At least one of inner and outer surfaces of the cover 630 may be provided with a prism pattern. Also, a fluorescent substance may be applied to at least one of the inner and outer surfaces of the cover 630.

Since the light generated from the light emitting device packages 644 is outwardly emitted through the cover 630, the cover 630 should have high light transmittance and heat resistance sufficient to endure heat generated from the light emitting device packages 644. To this end, the cover 630 may be made of polyethylene terephthalate (PET), polycarbonate (PC), polymethyl methacrylate (PMMA), or the like.

The end caps 650 may be disposed at the opposite ends of the body 610, and function to seal a power supply unit (not shown). Each end cap 650 is formed with power pins 652, so that the lighting apparatus 600 according to the illustrated embodiment may be directly connected to a terminal, from which an existing fluorescent lamp has been removed, without an additional connector.

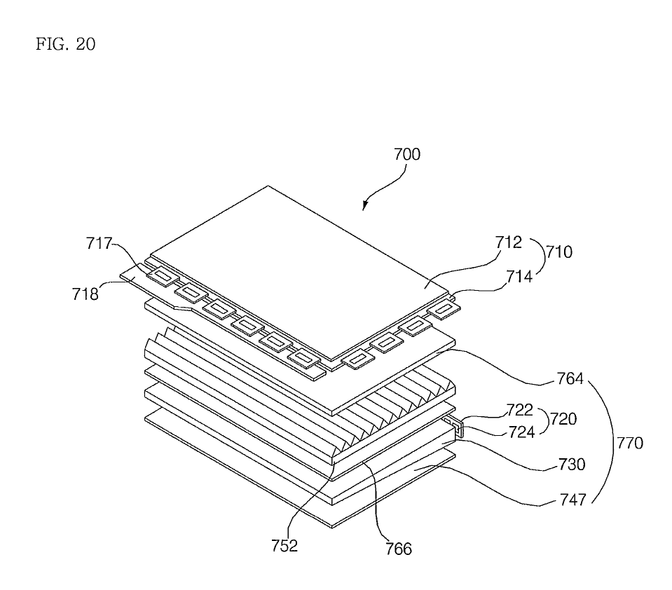

FIG. 20 is an exploded perspective view illustrating a liquid crystal display apparatus including a light emitting device according to an exemplary embodiment.

FIG. 20 illustrates an edge-light type liquid crystal display apparatus. The liquid crystal display apparatus, which is designated by reference numeral 700, may include a liquid crystal display panel 710 and a backlight unit 770 for supply of light to the liquid crystal display panel 710.

The liquid crystal display panel 710 may display an image using the light supplied from the backlight unit 770. The liquid crystal display panel 710 may include a color filter substrate 712 and a thin film transistor substrate 714, which face each other with liquid crystals interposed therebetween.

The color filter substrate 712 may realize the color of an image displayed through the liquid crystal display panel 710.

The thin film transistor substrate 714 is electrically connected to a printed circuit board (PCB) 718, on which a plurality of circuit elements is mounted, by means of a drive film 717. The thin film transistor substrate 714 may apply drive voltage provided by the PCB 718 to liquid crystals in response to a drive signal transmitted from the PCB 718.

The thin film transistor substrate 714 may include pixel electrodes and thin film transistors in the form of thin films formed on another substrate made of a transparent material such as glass or plastic.

The backlight unit 770 includes a light emitting device module 720 to emit light, a light guide plate 730 to change light emitted from the light emitting device module 720 into planar light and to provide the planar light to the liquid crystal display panel 710, a plurality of films 752, 766 and 764 to enhance uniformity in luminance distribution and vertical light incidence of light emerging from the light guide plate 730, and a reflective sheet 747 to reflect light emitted rearwards from the light guide plate 730 toward the light guide plate 730.

The light emitting device module 720 may include a plurality of light emitting device packages 724 and a PCB 722 on which the plural light emitting device packages 724 are mounted to form an array. In this case, reliability of the bent light emitting device packages 724 mounted on the PCB 722 may be improved.

The backlight unit 770 may include a diffusion film 766 to diffuse light incident thereupon from the light guide plate 730 toward the liquid crystal display panel 710, and a prism film 752 to converge the diffused light so as to enhance vertical light incidence. The backlight unit 770 may further include a protective film 764 to protect the prism film 752.

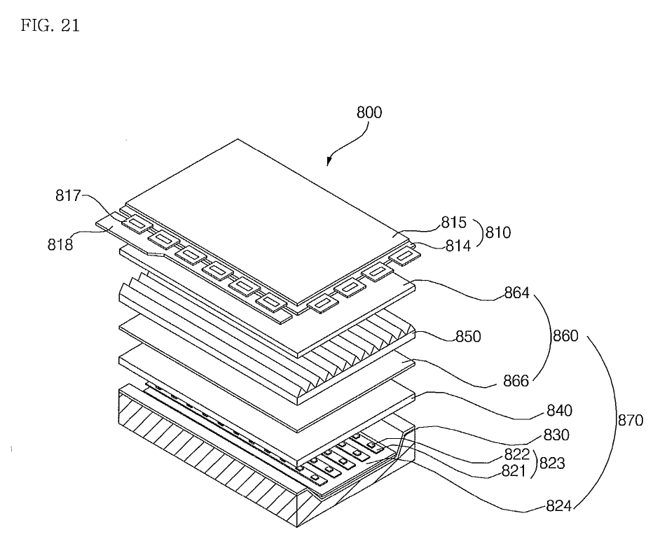

FIG. 21 is an exploded perspective view illustrating a liquid crystal display apparatus including a light emitting device according to an exemplary embodiment. Here, the same configuration as that illustrated in FIG. 20 will not be repeatedly described in detail.

FIG. 21 illustrates a direct type liquid crystal display apparatus. The liquid crystal display apparatus, which is designated by reference numeral 800, may include a liquid crystal display panel 810 and a backlight unit 870 for supply of light to the liquid crystal display panel 810.

Since the liquid crystal display panel 810 is similar to that of FIG. 23, no detailed description will be given thereof.

The backlight unit 870 may include a plurality of light emitting device modules 823, a reflective sheet 824, a lower chassis 830 in which the light emitting device modules 823 and reflective sheet 824 are accommodated, a diffusion plate 840, and a plurality of optical films 860, the diffusion plate 840 and the optical films 860 being disposed over the light emitting device modules 823.

Each light emitting device module 823 may include a plurality of light emitting device packages 822, and a PCB 821 on which the plural light emitting device packages 822 are mounted to form an array. The reflective sheet 824 reflects light generated by the light emitting device packages 822 toward the liquid crystal display panel 810, thereby achieving an enhancement in light utilization efficiency.

Meanwhile, the light generated from the light emitting device modules 823 is incident upon the diffusion plate 840. The optical films 860 are disposed over the diffusion plate 840. The optical films 860 may be comprised of a diffusion film 866, a prism film 850 and a protective film 864.

As is apparent from the above description, a light emitting device enables an irregularity portion to be formed at a side surface of a light emitting structure.

Also, since an irregularity portion is formed at a side surface of a light emitting structure in a light emitting device, luminous efficiency of the light emitting device may be enhanced.

In accordance with a method for manufacturing a light emitting device, an irregularity portion is easily formed at a side surface of a light emitting structure, thereby achieving an enhancement in operation convenience.

Although embodiments have been described with reference to a number of illustrative embodiments thereof, it should be understood that numerous other modifications and applications may be devised by those skilled in the art that will fall within the intrinsic aspects of the embodiments. More particularly, various variations and modifications are possible in concrete constituent elements of the embodiments. In addition, it is to be understood that differences relevant to the variations and modifications fall within the spirit and scope of the present disclosure defined in the appended claims.

What is claimed is:

1. A light emitting device comprising:
a light emitting structure comprising a first semiconductor layer, a second semiconductor layer, and an active layer disposed between the first and second semiconductor layers, the light emitting structure being made of a nitride semiconductor having a hexagonal crystal structure; and
an irregularity portion formed at a side surface of the light emitting structure,
wherein the irregularity portion has a pyramid shape with at least two faces, and at least one face of the pyramid shape comprises a non-polar face of the hexagonal crystal structure.

2. The light emitting device according to claim 1, wherein the non-polar face is an M-face {1-100}.

3. The light emitting device according to claim 1, wherein the pyramid shape comprises a vertical angle which is an obtuse angle.

4. The light emitting device according to claim 3, wherein the vertical angle is 120 degrees.

5. The light emitting device according to claim 1, wherein the light emitting structure comprises a square shape at an outer periphery of an upper surface thereof, and four faces of the square shape are semi-polar faces of the hexagonal crystal structure.

6. The light emitting device according to claim 1, wherein the light emitting structure comprises an inclined surface at the side surface thereof.

7. The light emitting device according to claim 1, further comprising a substrate disposed at a lower surface of the first semiconductor layer.

8. The light emitting device according to claim 1, further comprising:
a first electrode electrically connected to the first semiconductor layer; and
a second electrode disposed on the second semiconductor layer.

9. The light emitting device according to claim 8, wherein the first electrode is disposed at an exposed upper surface of the first semiconductor layer.

10. The light emitting device according to claim 1, further comprising an intermediate layer disposed between the active layer and the second semiconductor layer.

11. The light emitting device according to claim 1, further comprising a light transmitting electrode layer disposed on the second semiconductor layer.

12. The light emitting device according to claim 1, wherein the irregularity portion is formed by a wet etching method.

13. The light emitting device according to claim 7, further comprising a buffer layer disposed between the substrate and the first semiconductor layer.

14. The light emitting device according to claim 1, wherein the active layer comprises:
at least one well layer; and
at least one barrier layer having a greater band gap than the well layer.

15. The light emitting device according to claim 14, wherein the well layer and the barrier layer are alternately laminated.

16. A method for manufacturing a light emitting device comprising:
providing a substrate having a hexagonal crystal structure;
growing a nitride semiconductor layer, which has the hexagonal crystal structure and is biased by 30 degrees with respect to a hexagonal crystal orientation of the substrate, on the substrate;
disposing a plurality of mask patterns having a square shape on the nitride semiconductor layer;
dividing the nitride semiconductor layer into a plurality of light emitting structures; and
forming an irregularity portion throughout a side surface of each light emitting structure by wet etching of the nitride semiconductor layer, wherein:
the substrate has a datum level formed as an A-face of the hexagonal crystal structure; and
each of the square shaped mask patterns has a structure in which an angle between a side surface thereof and the datum level is formed to have a range of 0 degree to 30 degrees or a range of 30 degrees to 45 degrees.

17. The method for manufacturing the light emitting device according to claim 16, wherein each mask pattern comprises silicon dioxide (SiO₂).

18. The method for manufacturing the light emitting device according to claim 16, wherein the nitride semiconductor layer comprises a first semiconductor layer, a second semiconductor layer, and an active layer disposed between the first and second semiconductor layers.

19. The method for manufacturing the light emitting device according to claim 16, wherein the forming the irregularity portion is carried out using at least one etching solution selected from the group consisting of KOH, HF, NaOH, and H₃PO₄.

20. The method for manufacturing the light emitting device according to claim 16, further comprising exposing the first semiconductor layer, forming a first electrode on the first semiconductor layer, and forming a second electrode on the second semiconductor layer.
